(19) United States
(12) Patent Application Publication
(10) Pub. No.: US 2009/0064932 A1
(43) Pub. Date: Mar. 12, 2009

(54) Apparatus for HDP-CVD and method of forming insulating layer using the same

(75) Inventors: Ki Hyun Kim, Yongin-si (KR); Doug Yong Sung, Suwon-si (KR); Moon Hyeong Han, Seoul (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., Ltd., Suwon-si (KR)

(21) Appl. No.: 12/219,443

(22) Filed: Jul. 22, 2008

(30) Foreign Application Priority Data
Aug. 31, 2007 (KR) 10-2007-0088021

(51) Int. Cl. C23C 16/22; C23C 16/52

(52) U.S. Cl. 118/715; 427/255.18; 427/255.28; 216/37

(57) ABSTRACT

Disclosed herein are an apparatus for high-density plasma chemical vapor deposition and a method of forming an insulating layer using the same. The use of the apparatus and method enables efficient formation of the insulating layer in the gap between semiconductor devices with a high aspect ratio by dispersing a total demand amount of gas in the formation process.

The high-density plasma chemical vapor deposition apparatus includes a plurality of gas suppliers to supply a gas into a chamber and to form an insulating layer between semiconductor devices, each of the gas suppliers including a gas injection valve to perform an on/off operation and a valve controller to control the on/off operation of the gas injection valve and to disperse a total demand amount of the gas.

### CROSS-REFERENCE TO RELATED APPLICATIONS

This application claims the benefit of Korean Patent Application No. 2007-0088021, filed on Aug. 31, 2007 in the Korean Intellectual Property Office, the disclosure of which is incorporated herein by reference.

### BACKGROUND

1. Field

The present invention relates to an apparatus for high-density plasma chemical vapor deposition and a method of forming an insulating layer using the same. More specifically, the present invention relates to a high-density plasma chemical vapor deposition apparatus used in formation of an insulating layer between semiconductor devices and a method of forming an insulating layer with the same.

2. Description of the Related Art

Chemical vapor deposition (hereinafter, referred to simply as “CVD”) is a semiconductor processing technique to form single-crystalline films, e.g., a semiconductor layer or an insulating layer on the surface of a wafer using chemical reactions. Such CVD requires a subsequent process, i.e., heating a wafer to high temperatures, thus disadvantageously causing deterioration of a semiconductor device on the wafer. In addition, recent rapid development of semiconductor fabrication techniques has brought about high-integration of semiconductor devices and increased metal wiring density, thus making it difficult to completely fill a gap between the metal wires using CVD.

Accordingly, in an attempt to maximize the ability to fill the gap between metal wires, i.e., gap-filling capability, several processes of fabricating an interlayer dielectric film have been developed. One of such processes is high density plasma chemical vapor deposition (hereinafter, referred to as “HDP-CVD”). HDP-CVD is a method of depositing an insulating layer on a wafer, which includes producing high-density plasma ions by applying an electric field and a magnetic field and decomposing a source gas, to exhibit high ionization efficiency, as compared to conventional Plasma-Enhanced Chemical Vapor Deposition (PECVD). According to the HDP-CVD, both a source power to generate plasma and a bias power to etch the interlayer dielectric film on the wafer are applied during the deposition of the interlayer dielectric film, thereby concurrently performing deposition and sputtering etch of the interlayer dielectric film.

During these processes, the process gas supplied into a reactor must be uniformly distributed around the wafer, so as to uniformly deposit an interlayer dielectric film on the surface thereof and thereby to realize a high quality film.

Similarly, during the etching, the process gas must be uniformly distributed, in order to realize uniform sputtering over the surface and thereby to perform desired etching.

### SUMMARY

As the design rule of semiconductor devices shrinks significantly to 70 nm or less, an aspect ratio of regions to fill the gap rapidly decreases. For this reason, with a conventional HDP-CVD method, it is increasingly difficult to realize satisfactory gap-filling capabilities.

Furthermore, a conventional HDP-CVD suggests only a method of uniformly distributing a process gas and thus fails to provide solutions for problems, e.g., overhangs and voids, caused by reduction of the semiconductor device's design rule.

The foregoing and/or other aspects are achieved by providing a high-density plasma chemical vapor deposition apparatus, including: a plurality of gas suppliers supplying a gas into a chamber and forming an insulating layer between semiconductor devices, each of the gas suppliers including a gas injection valve performing an on/off operation; and a valve controller controlling the on/off operation of the gas injection valve and dispersing a total demand amount of the gas.

The valve controller may allow the gas injection valve to periodically perform the on/off operation and thereby to periodically supply the gas.

The gas supplier may further include a mass flow controller to render an amount of the gas not more than a predetermined level.

The gas may include first and second deposition gases to deposit the insulating layer between semiconductor devices and an etch gas to etch the insulating layer.

The gas injection valve may include a first gas injection valve performing an on/off operation and thereby supplying the first deposition gas, a second gas injection valve performing an on/off operation and thereby supplying the etch gas, or a third gas injection valve performing an on/off operation and thereby supplying the second deposition gas.

The valve controller may include a first valve controller controlling the operation of the first gas injection valve, a second valve controller controlling the operation of the second gas injection valve, or a third valve controller controlling the operation of the third gas injection valve.

The first and second deposition gases may differ in constituent atoms, e.g., silicon (Si) and oxygen (O₂), respectively, and the etch gas may contain fluorine (F).

The valve controller may control the on/off operation of the gas injection valve, using at least one of a gas injection time, a number of times the gas injection valve performs the on/off operation for the gas injection time, an initial duty ratio, an end duty ratio, a time variation ratio and a number of times of a gas injection loop runs.

The valve controller differentially may control the on/off operation of the gas injection valve according to a distance between the semiconductor devices.

More specifically, when the distance between semiconductor devices is less than a standard distance, the valve controller gradually varies an “On” time of the gas injection valve.

When the distance between the semiconductor devices is less than a standard distance, the valve controller gradually increases the “On” time of the gas injection valve to a standard point, and when the “On” time reaches the standard point, the valve controller begins to gradually decrease the “On” time of the gas injection valve.

When the distance between the semiconductor devices is not less than a standard distance, the valve controller maintains the “On” time of the gas injection valve.

The foregoing and/or other aspects are achieved by providing a method of forming an insulating layer with a high-density plasma chemical vapor deposition apparatus, including: dispersing a total demand amount of deposition gas to deposit an insulating layer between semiconductor devices; dispersing a total demand amount of etch gas to etch the insulating layer; and repeating the deposition and etching processes until a thickness of the insulating layer is adjusted to a desired level.

The deposition gas may include first and second deposition gases having different constituent atoms, e.g., silicon (Si) and oxygen (O₂), respectively.

The etch gas may include a fluorine (F)-containing gas.

After the etching process, a hydrogen (H₂)-containing gas may be supplied onto the insulating layer to remove fluorine (F) present thereon.

So as to dispersedly supply the total demand amount of deposition gas, a valve controller controls an on/off operation of a gas injection valve using various factors including a gas injection time, a number of times the gas injection valve performs the on/off operation for the gas injection time, an initial duty ratio, an end duty ratio, a time variation ratio and a number of times a gas injection loop runs.

The factors may be varied depending upon a distance between semiconductor devices.

During the supply of the deposition and etch gases, the on/off operation of the gas injection valves may be controlled to vary depending upon the distance between the semiconductor devices.

When the distance between the semiconductor devices is less than a standard distance, the valve controller gradually varies an “On” time of the gas injection valve.

More specifically, when the distance between the semiconductor devices is less than a standard size, the valve controller gradually increases the “On” time of the gas injection valve to a standard point, and when the “On” time reaches the standard point, the valve controller begins to gradually decrease the “On” time of the gas injection valve.

When the distance between semiconductor devices is not less than a standard size, the valve controller maintains the “On” time of the gas injection valve.

When a thickness of the insulating layer is adjusted to a desired level, the gas injection is kept in an “On” state and the deposition gas is then supplied, until the insulating layer is completely formed.

The foregoing and/or other aspects are achieved by providing a method of forming an insulating layer between semiconductor devices, including: supplying gas into a chamber to form an insulating layer between the semiconductor devices by performing an on/off operation of at least one gas injection valve, an “On” time of the at least one gas injection valve being gradually increased to a standard point and then gradually decreased from the standard point when a distance between the semiconductor devices is less than a standard distance, and the “On” time of the at least one gas injection valve being maintained when the distance between the semiconductor devices is not less than the standard distance.

The gas may include first and second deposition gases to deposit the insulating layer and an etch gas to etch the insulating layer.

The on/off operation of the at least one gas injection valve may be controlled in accordance with at least one of a gas injection time, a number of times the gas injection valve performs the on/off operation for the gas injection time, an initial duty ratio, an end duty ratio, a time variation ratio and a number of times a gas injection loop runs.

Additional aspects and/or advantages will be set forth in part in the description which follows and, in part, will be obvious from the description, or may be learned by practice of the invention.

### BRIEF DESCRIPTION OF THE DRAWINGS

These and/or other aspects and advantages will become apparent and more readily appreciated from the following description of the embodiments, taken in conjunction with the accompanying drawings of which:

FIG. 1 is a sectional view illustrating a structure of a high-density plasma chemical vapor deposition apparatus according to embodiments;

FIG. 2 is a graph showing an operation state of a gas injection valve in one cycle as a function of time according to an embodiment;

FIG. 3 is a graph showing an operation state of a gas injection valve in one cycle as a function of time according to an embodiment;

FIG. 4 is a graph showing an operation state of a gas injection valve in an overall cycle as a function of time according to an embodiment;

FIG. 5 is a graph showing an operation state of a gas injection valve in an overall cycle as a function of time according to an embodiment; and

FIG. 6 is a control flow chart illustrating a process of forming an insulating layer with the HDP-CVD apparatus according to an embodiment.

### DETAILED DESCRIPTION OF THE EMBODIMENTS

Reference will now be made in detail to the embodiments, examples of which are illustrated in the accompanying drawings, wherein like reference numerals refer to the like elements throughout. The embodiments are described below to explain the present invention by referring to the figures.

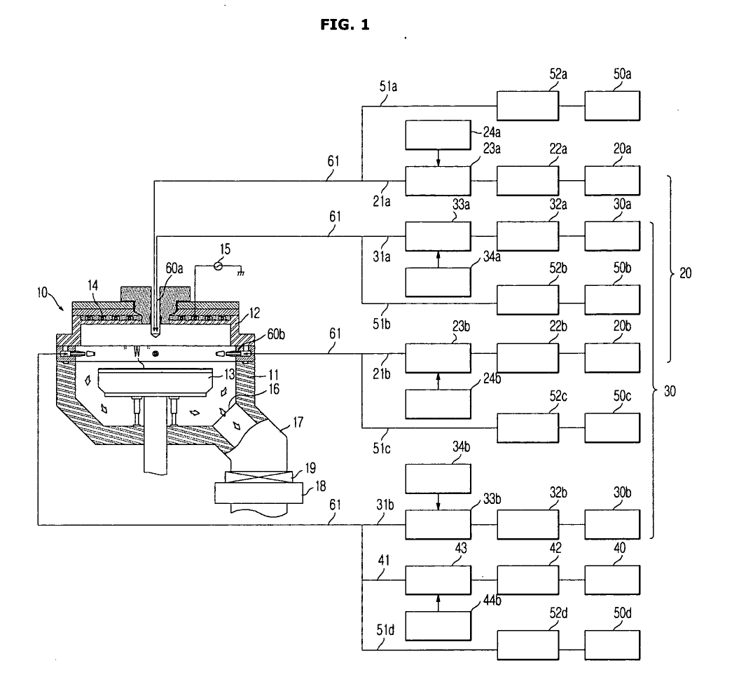

First, as shown in FIG. 1, a chamber 10 to process a semiconductor substrate W includes a cylindrical body 11 with an opened-top and a cover 12 to cover the opened-top of the body 11. The processing of the semiconductor substrate W using an apparatus for high-density plasma chemical vapor deposition (hereinafter, referred to as a “HDP-CVD” apparatus) includes forming an insulating layer between semiconductor devices on the semiconductor substrate W, including depositing an insulating layer and etching the same.

A chuck 13 to support the semiconductor substrate W is arranged in the chamber 10. The chuck 13 is an electrostatic chuck to fix the semiconductor substrate W via an electrostatic force. A bias powder to induce a plasma process gas onto the semiconductor substrate W is applied to the chuck 13.

An induction coil 14 is arranged on the top of the cover 12, which produces an electromagnetic field rendering the processing gas, introduced into the chamber 10, to be in a plasma state, and a high-frequency power supply 15 is connected to the induction coil 14. Meanwhile, the cover 12 may be made of an insulating material, for example, aluminum oxide and ceramic, through which high-frequency energy flows.

A discharge outlet 16 is arranged in the lower part of the body 11, which discharges by-products and gas residues from the chamber 10 to the outside. The discharge outlet 16 is connected to a discharge pipe 17 provided with a vacuum pump 18 to keep the chamber 10 under vacuum and with a pressure controller 19.

Furthermore, a plurality of gas suppliers 20, 30, 40 and 50 to supply a gas into the chamber 10 are arranged in the lower part and in the upper central part of the cover 12, so that an insulating layer can be formed between semiconductor devices by performing deposition and etch processes in the chamber 10.

The gas suppliers 20 (20a-b), 30 (30a-b), 40 and 50 (50a-d) include gas supply lines 21 (21a-b), 31 (31a-b), 41, 51 (51a-d) and 61, mass flow controllers 22 (22a-b), 32 (32a-b), 42 and 52 (52a-d), gas injection valves 23 (23a-b), 33 (33a-b) and 43, and valve controllers 24 (24a-b), 34 (34a-b) and 44.

The gas supply lines 21, 31, 41, 51 and 61 include a first gas supply line 21 to supply a first deposition gas, a second gas supply line 31 to supply an etch gas, a third gas supply line 41 to supply a second deposition gas and a fourth gas supply line 51 to supply a process gas, and further include a gas supply line 61 to connect the plurality of the gas supply lines 21, 31, 41, 51 and 61 with one another.

The gas supply lines 21, 31, 41, 51 and 61 serve as a passage, allowing the gas stored in gas supply parts 25, 35, 45 and 55 to be supplied to the chamber 10, which include lines to discharge a gas in the upper and side parts of the chamber 10. Each of the lines 21, 31, 41, 51 and 61 may concurrently or sequentially discharge one or more gases.

The gas includes first and second deposition gases used to deposit an insulating layer between semiconductor devices and an etch gas used to etch the insulating layer. The first and second deposition gases may have different constituent atoms, e.g., silicon (Si) and oxygen (O₂), respectively, for example, and the etch gas may contain a fluorine (F) atom, for example. In addition, the process gas may contain a helium (He) atom, for example.

When the first deposition gas is silane (SiH₄) that contains a silicon (Si) atom and the second deposition gas is oxygen (O₂), for example, the first and second deposition gases react with each other via chemical vapor deposition to produce a silicon dioxide (SiO₂) film. The SiO₂ film thus produced is deposited between the semiconductor devices.

The mass flow controllers 22, 32, 42 and 52 make an amount of the gas supplied to gas supply nozzles 60a and 60b within a predetermined level. More specifically, the mass flow controllers 22, 32 and 42 primarily control an amount of the gas supplied to the gas injection valves 23, 33 and 43 by filling a predetermined level or less of the gas into the shearing line of the gas injection valves 23, 33 and 43.

Herein, the predetermined level is a standard amount set to primarily decrease the amount of the gas supplied from the gas supply parts 25, 35, 45 and 55, which is preferably determined based upon the cross-sectional area of the gas supply lines 21, 31, 41 and 51 or the size of the gas supply nozzle 60.

The gas injection valves 23, 33 and 43 include a first gas injection valve 23 to perform an on/off operation and thereby supply the first deposition gas, a second gas injection valve 33 to perform an on/off operation and thereby supply the etch gas, and a third gas injection valve 43 to perform an on/off operation and thereby supply the second deposition gas, and may further include a fourth gas injection valve to perform an on/off operation and thereby supply the process gas.

In an “On” state, the gas injection valves 23, 33 and 43 perform an opening operation, allowing the gas supply lines 21, 31 and 41 to open and thereby induce supply of the gas to the gas supply nozzles 60a and 60b. In an “Off” state, the gas injection valves 23, 33 and 43 perform a closing operation, blocking the supply of the gas.

The valve controllers 24, 34 and 44 include a first valve controller 24 to control the operation of the first gas injection valve 23, a second valve controller 34 to control the operation of the second gas injection valve 33, and a third valve controller 44 to control the operation of the third gas injection valve 43. The gas injection valves 23, 33 and 43 control the on/off operation to uniformly supply a total demand amount of the gas.

That is to say, the valve controllers 24, 34 and 44 allow the gas injection valves 23, 33 and 43 to periodically perform the on/off operation and thus to periodically supply a standard amount or less of gas. The term “standard amount” used herein refers to a predetermined amount of the gas discharged from the gas supply nozzle 60 in one interval. The valve controllers 24, 34 and 44 periodically supply a small amount of gas which is not more than the standard amount, thereby forming a uniform and thin insulating layer between the semiconductor devices.

More specifically, the valve controllers 24, 34 and 44 control the on/off operation of the gas injection valves 23, 33 and 43 depending upon factors such as a gas injection time, the number of times the gas injection valves 23, 33 and 43 perform the on/off operation during the gas injection time, an initial duty ratio, an end duty ratio, and a time variation ratio, for example.

In addition, a total gas injection cycle is obtained by the number of times a gas injection loop runs, i.e., with N-times repetition of one cycle in which the gas injection valves 23, 33 and 43 perform the on/off operation several times. The term “gas injection time” used herein refers to a total gas injection time per cycle. The term “initial duty ratio” used herein refers to a proportion of the “On” time during which the gas injection valves 23, 33 and 43 first perform the on/off operation. The term “end duty ratio” used herein refers to a proportion of the “On” time during which the gas injection valves 23, 33 and 43 finally perform the on/off operation.

In addition, in order to gradually increase or decrease the “On” operation time of the gas injection valves 23, 33 and 43, the valve controllers 24, 34 and 44 control the “On” operation time depending upon the time variation ratio.

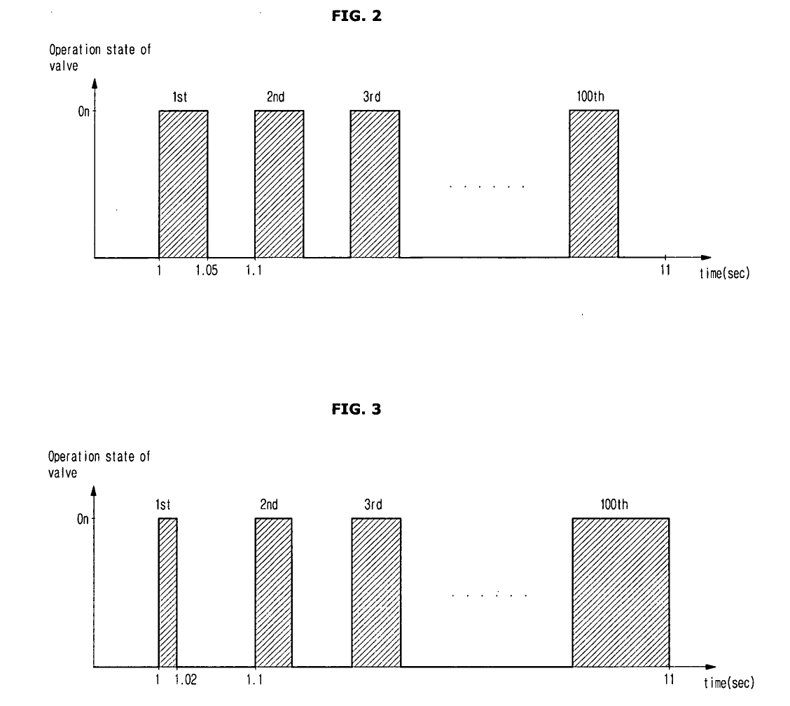

Referring to FIG. 2, the aforementioned description will be illustrated in more detail. For example, when the gas injection time is 10 sec per cycle, the number of times the gas injection valve performs the on/off operation for the gas injection time is 100, the number of times of the gas injection loop runs is 5, and the final and end duty ratios are 50%, the valve controller causes the gas injection valve to repeat the “On” operation 100 times for 0.05 sec and the “Off” operation for 0.05 sec per cycle, and causes the gas injection valve to repeat four more cycles following the first cycle.

Referring to FIG. 3, for example, when the gas injection time is 10 sec per cycle, the number of times the gas injection valve performs the on/off operation for the gas injection time is 100, the time variation ratio is 110%, and the final and end duty ratios are 20% and 100%, respectively, in the first (on/off) duration, the valve controller allows the gas injection valve to be in an “On” state for 0.02 sec and an “Off” state for 0.08 sec, and in the 100^{th} duration, the valve controller allows the gas injection valve to be in an “On” state for 0.1 sec. In addition, the valve controller makes an “On” time for the first duration of the gas injection valve 1.1 longer than an “On” time for the second duration thereof.

Meanwhile, the valve controllers 24, 34 and 44 differentially control the on/off operation of the gas injection valves according to a distance between semiconductor devices. The term “distance between semiconductor devices” refers to a gap between semiconductor devices, also known as an “aspect ratio”. Accordingly, when the distance between the semiconductor devices is close, the aspect ratio is large.

That is to say, when the distance between semiconductor devices is smaller than a predetermined level, the valve controllers 24, 34 and 44 gradually vary the “On” time of the gas injection valves 23, 33 and 43. More specifically, the valve controllers 24, 34 and 44 gradually increase the “On” time of the gas injection valves 23, 33 and 43 to a standard point. When the “On” time reaches the standard point, the valve controllers 24, 34 and 44 gradually decrease the “On” time of the gas injection valves 23, 33 and 43. The term “standard point” used herein refers to a time serving as a base, leading to variation in “On” times of the gas injection valve.

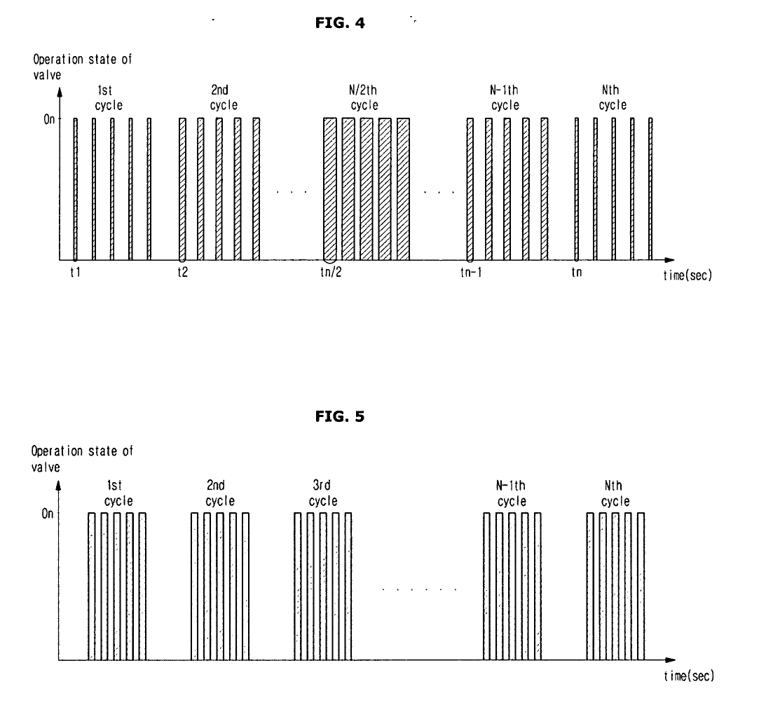

Hereinafter, in the case where the distance between semiconductor devices is smaller than a predetermined level, a control-operation of the gas injection valve will be illustrated with reference to FIG. 4 in detail.

The total number of gas injection cycles includes N cycles. As shown in FIG. 4, as the cycle count increases, the “On” time of the gas injection valves 23, 33 and 43 is gradually increased. Then, when the cycle reaches the standard point, i.e., the N/2^{th} cycle, the “On” time of the gas injection valves 23, 33 and 43 is gradually decreased.

This behavior is represented by the following equations:

t₁<t₂<t_{n/2}, t_{n/2}>tₙ₋₁>tₙ

The valve controllers 24, 34 and 44 vary the “On” time of the gas injection valves 23, 33 and 43 and thereby efficiently form an insulating layer within the gap with a large aspect ratio. That is, the valve controllers 24, 34 and 44 control the “On” time of the gas injection valves 23, 33 and 43 to supply a gradually increasing amount of the deposition gas, thus preventing formation of voids.

In addition, when the distance between the semiconductor devices is not more than the predetermined level, as shown in FIG. 5, the controllers 24, 34 and 44 keep the “On” time of the gas injection valves 23, 33 and 43 constant.

Meanwhile, according to an embodiment, the valve controllers 24, 34 and 44 control the gas injection valves 23, 33 and 43, separately. However, the present invention is not limited thereto. In other words, one valve controller may control a plurality of the gas injection valves 23, 33 and 43.

Hereinafter, a process of forming an insulating layer with an HDP-CVD apparatus will be illustrated.

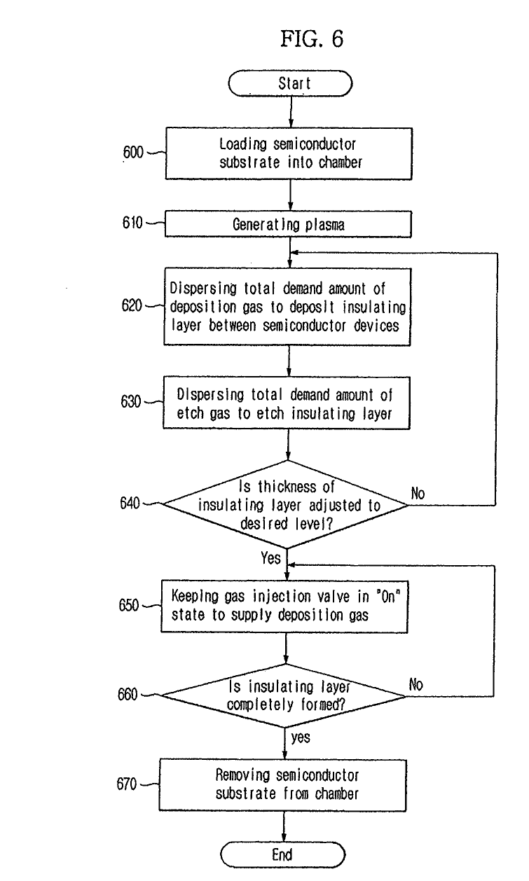

FIG. 6 is a control flow chart illustrating a process of forming an insulating layer using an HDP-CVD apparatus according to an embodiment.

Referring to FIG. 6, a semiconductor substrate W is loaded into the chamber 10 and fixed on the chuck 13 of the chamber 10 (600). A helium (He)-containing process gas (inert gas) is fed into the chamber 10. The vacuum pump 18 and the pressure controller 19 maintain a vacuum in the chamber 10. Power is applied to the induction coil 14 to transform the process gas into a plasma (610).

Then, in order to deposit an insulating layer between semiconductor devices in the presence of plasma, a total demand amount of the deposition gas is discharged and supplied (620). The deposition gas includes first and second deposition gases with different constituent atoms, e.g., silicon (Si) and oxygen (O₂), respectively.

That is, the first and second deposition gases are supplied into the plasma-containing chamber 10 to deposit an insulating layer on the semiconductor substrate W. At this time, the helium-containing process gas is supplied through all of the gas supply lines into the chamber 10. While the process gas is supplied, the first and third mass flow controllers 22 and 42 adjust the first and second deposition gases within a predetermined level. The first and second deposition gases are filled into the shearing line of the first and third gas injection valves 23 and 43.

In addition, in order to uniformly supply a total demand amount of deposition gas, the valve controllers 24, 34 and 44 control the on/off operation of the gas injection valves 23, 33 and 43 by varying various factors such as a gas injection time, a number of times the gas injection valves 23, 33 and 43 perform an on/off operation during the gas injection time, an initial duty ratio, an end duty ratio, a time variation ratio and a number of times a gas injection loop runs.

Furthermore, the distance between semiconductor devices determines the factors, e.g., the gas injection time, the number of times the gas injection valves 23, 33 and 43 perform the on/off operation during the gas injection time, the initial duty ratio, the end duty ratio, the time variation ratio and the number of times of the gas injection loop runs, and furthermore the manner in which on/off operation of the gas injection valves 23, 33 and 43 is controlled.

When the distance between semiconductor devices is below a predetermined level, the valve controllers 24, 34 and 44 gradually vary the “On” time of the gas injection valves 23, 33 and 43. More specifically, the valve controllers 24, 34 and 44 gradually increase the “On” time of the gas injection valves 23, 33 and 43 to a standard point. At the standard point, the valve controllers 24, 34 and 44 gradually decrease the “On” time of the gas injection valves 23, 33 and 43.

In addition, when the distance between semiconductor devices is not less than the predetermined level, the valve controllers 24, 34 and 44 maintain the “On-time” of the gas injection valves 23, 33 and 43.

After the deposition, a total demand amount of etch gas is dispersed to etch the insulating layer (630).

When the primarily-deposited insulating layer is etched to a predetermined thickness using a fluorine (F)-containing etch gas, a part (overhangs) of the primarily-deposited insulating layer, which is on the upper edges of bit lines, is over-etched as compared to the remaining part. As a result, the “bottleneck” phenomenon between the bit lines is solved and a subsequent insulating layer is then easily deposited.

Similar to the deposition process, in an etching process, in order to disperse the total demand amount of deposition gas, the valve controller 34 controls the on/off operation of the gas injection valves 23, 33 and 43 by varying various factors such as a gas injection time, the number of times the gas injection valve 33 performs an on/off operation for the gas injection time, an initial duty ratio, an end duty ratio, a time variation ratio and the number of times a gas injection loop runs. A more detailed description of the control behavior of the valve controller 34 is given above.

After the etching process, a hydrogen (H₂)-containing gas is supplied onto the insulating layer to remove the fluorine (F) present thereon.

By performing a subsequent deposition process on the fluorine (F)-free insulating layer thus obtained, it is possible to prevent a two-phase interface caused by fluorine (F) residues and thereby to form an insulating layer free of any two-phase interface.

Then, whether or not the thickness of the insulating layer is adjusted to a desired level is determined (640). When the insulating layer has a desired thickness, the gas injection valves 23 and 43 are kept in an “On” state and the deposition gas is then supplied until the insulating layer is completely formed (650). That is, by keeping the gas injection valves 23 and 43 completely open, the deposition process can be performed as rapidly as possible.

More specifically, an injection method according to the present embodiments (dispersal of the total demand amount of gas) is applied only to parts of the insulating layer susceptible to gap-filling, and a general gas injection method is applied to the remaining parts thereof, thereby efficiently performing the gap-filling.

Meanwhile, to determine whether the thickness of the insulating layer is adjusted to a desired level, the number of times deposition and etching processes are performed is calculated. When the calculated value reaches the predetermined level, the thickness of the insulating layer is assumed to be within the desired level.

In the process 640, unless the insulating layer has reached a desired thickness, the several processes following the process 620, i.e., deposition and etching processes, are repeated.

Whether the insulating layer is completely formed is determined (660). When the formation of the insulating layer is completed, the semiconductor substrate W is removed from the chamber 10 (670). When the formation of the insulating layer is not completed, the operation returns to process 650 and the gas injection valve is kept in an “On” state to supply deposition gas.

As apparent from the foregoing, according to the present embodiments, a hybrid high-density plasma chemical vapor deposition (HDP-CVD) apparatus is provided which is capable of realizing high-density plasma chemical vapor deposition and a gas injection method that disperses a total demand amount of gas to form an insulating layer is provided. In addition, the method of forming an insulating layer using the HDP-CVD apparatus realizes efficient formation of an insulating layer between semiconductor devices.

Furthermore, after the etching process, by supplying a hydrogen (H₂)-containing gas to the insulating layer to remove the fluorine (F) present thereon, it is possible to prevent a two-phase interface caused by fluorine (F) residues and thereby to form an insulating layer free of any two-phase interface.

In conclusion, the present embodiments are capable of preventing voids caused by semiconductor devices having a high aspect ratio and by two-phase interfaces, thus improving the reliability and fabrication efficiency of semiconductor devices.

Although a few embodiments have been shown and described, it would be appreciated by those skilled in the art that changes may be made in these embodiments without departing from the principles and spirit of the invention, the scope of which is defined in the claims and their equivalents.

What is claimed is:

1. A high-density plasma chemical vapor deposition apparatus, comprising:
a plurality of gas suppliers supplying a gas into a chamber and forming an insulating layer between semiconductor devices, each of the gas suppliers including a gas injection valve performing an on/off operation; and a valve controller controlling the on/off operation of the gas injection valve and dispersing a total demand amount of the gas.

2. The high-density plasma chemical vapor deposition apparatus according to claim 1, wherein the valve controller allows the gas injection valve to periodically perform the on/off operation and thereby to periodically supply the gas.

3. The high-density plasma chemical vapor deposition apparatus according to claim 1, wherein the gas supplier further includes a mass flow controller to render an amount of the gas not more than a predetermined level.

4. The high-density plasma chemical vapor deposition apparatus according to claim 1, wherein the gas includes first and second deposition gases to deposit the insulating layer between semiconductor devices and an etch gas to etch the insulating layer.

5. The high-density plasma chemical vapor deposition apparatus according to claim 4, wherein the gas injection valve includes a first gas injection valve performing an on/off operation and thereby supplying the first deposition gas, a second gas injection valve performing an on/off operation and thereby supplying the etch gas, or a third gas injection valve performing an on/off operation and thereby supplying the second deposition gas.

6. The high-density plasma chemical vapor deposition apparatus according to claim 5, wherein the valve controller includes a first valve controller controlling the operation of the first gas injection valve, a second valve controller controlling the operation of the second gas injection valve, or a third valve controller controlling the operation of the third gas injection valve.

7. The high-density plasma chemical vapor deposition apparatus according to claim 4, wherein the first and second deposition gases have different constituent atoms and include silicon (Si) and oxygen (O2), respectively, and the etch gas contains a fluorine (F) atom.

8. The high-density plasma chemical vapor deposition apparatus according to claim 1, wherein the valve controller controls the on/off operation of the gas injection valve, using at least one of a gas injection time, a number of times the gas injection valve performs the on/off operation for the gas injection time, an initial duty ratio, an end duty ratio, and a time variation ratio.

9. The high-density plasma chemical vapor deposition apparatus according to claim 8, wherein the valve controller differentially controls the on/off operation of the gas injection valve according to a distance between the semiconductor devices.

10. The high-density plasma chemical vapor deposition apparatus according to claim 9, wherein when the distance between semiconductor devices is less than a standard distance, the valve controller gradually varies an “On” time of the gas injection valve.

11. The high-density plasma chemical vapor deposition apparatus according to claim 10, wherein when the valve controller gradually varies the “On” time of the gas injection valve, the valve controller gradually increases the “On” time of the gas injection valve to a standard point, and when the “On” time reaches the standard point, the valve controller begins to gradually decrease the “On” time of the gas injection valve.

12. The high-density plasma chemical vapor deposition apparatus according to claim 9, wherein when the distance between semiconductor devices is not less than a standard distance, the valve controller maintains an “On” time of the gas injection valve.

13. A method of forming an insulating layer using a high-density plasma chemical vapor deposition apparatus, comprising:
dispersing a total demand amount of deposition gas to deposit an insulating layer between semiconductor devices;
dispersing a total demand amount of etch gas to etch the insulating layer; and
repeating the deposition and etching processes until a thickness of the insulating layer is adjusted to a desired level.

14. The method according to claim 13, wherein the deposition gas includes first and second deposition gases having different constituent atoms, the first and second deposition gases including silicon (Si) and oxygen (O₂), respectively.

15. The method according to claim 13, wherein the etch gas is a fluorine (F)-containing gas.

16. The method according to claim 13, wherein after the etching process, a hydrogen (H₂)-containing gas is supplied onto the insulating layer to remove fluorine (F) present thereon.

17. The method according to claim 13, wherein a valve controller of the high-density plasma chemical vapor deposition apparatus controls an on/off operation of a gas injection valve using factors including at least one of a gas injection time, a number of times the gas injection valve performs the on/off operation for the gas injection time, an initial duty ratio, an end duty ratio, a time variation ratio and a number of times a gas injection loop runs, in order to disperse the total demand amount of deposition gas.

18. The method according to claim 17, wherein the factors are varied depending upon a distance between semiconductor devices.

19. The method according to claim 18, wherein during the supply of the deposition and etch gases, the on/off operation of the gas injection valve is varied depending upon the distance between the semiconductor devices.

20. The method according to claim 19, wherein when the distance between semiconductor devices is less than a standard distance, the valve controller gradually varies an “On” time of the gas injection valve.

21. The method according to claim 20, wherein when the valve controller gradually varies the “On” time of the gas injection valve, the valve controller gradually increases the “On” time of the gas injection valve to a standard point, and when the “On” time reaches the standard point, the valve controller begins to gradually decrease the “On” time of the gas injection valve.

22. The method according to claim 19, wherein when the distance between semiconductor devices is not less than the standard distance, the valve controller maintains the “On” time of the gas injection valve.

23. The method according to claim 13, wherein when a thickness of the insulating layer is adjusted to a desired level, gas injection is kept in an “On” state and the deposition gas is then supplied until the insulating layer is completely formed.

24. A method of forming an insulating layer between semiconductor devices, comprising:
supplying gas into a chamber to form an insulating layer between the semiconductor devices by performing an on/off operation of at least one gas injection valve, an “On” time of the at least one gas injection valve being gradually increased to a standard point and then gradually decreased from the standard point when a distance between the semiconductor devices is less than a standard distance, and the “On” time of the at least one gas injection valve being maintained when the distance between the semiconductor devices is not less than the standard distance.

25. The method according to claim 24, wherein the gas includes first and second deposition gases to deposit the insulating layer and an etch gas to etch the insulating layer.

26. The method according to claim 24, wherein the on/off operation of the at least one gas injection valve is controlled in accordance with at least one of a gas injection time, a number of times the gas injection valve performs the on/off operation for the gas injection time, an initial duty ratio, an end duty ratio, a time variation ratio and a number of times a gas injection loop runs.
